(19) United States
(12) Patent Application Publication
(10) Pub. No.: US 2025/0115999 A1
(43) Pub. Date: Apr. 10, 2025

(54) COMPACT DYNAMIC LEVELING LIFT MECHANISM

(71) Applicant: Applied Materials, Inc., Santa Clara, CA (US)

(72) Inventors: Tuan Anh Nguyen, San Jose, CA (US); Rohith Kuruvath Karunakaran, Thrissur (IN)

(73) Assignee: Applied Materials, Inc., Santa Clara, CA (US)

(21) Appl. No.: 18/483,965

(22) Filed: Oct. 10, 2023

(51) Int. Cl. C23C 16/458; H01J 37/32; H01L 21/687

(52) U.S. Cl. CPC C23C 16/4581; H01J 37/32715; H01L 21/68742; H01L 21/68785

(57) ABSTRACT

Exemplary semiconductor processing chambers may include a chamber body. The chambers may include a bottom plate coupled with a bottom surface of the chamber body. The chambers may include a substrate support assembly disposed within the chamber body. The substrate support assembly may include a support plate and a support stem coupled with the support plate. The chambers may include a mounting bracket that couples the support stem with a lower surface of the bottom plate. The chambers may include a plurality of tilt actuators. Each of the tilt actuators may couple the mounting bracket with the lower surface of the bottom plate. Each of the tilt actuators may be operable to adjust a vertical distance between the lower surface of the bottom plate and the mounting bracket at a mounting site of the respective tilt actuator to adjust a planarity of the support plate relative to the bottom plate.

### TECHNICAL FIELD

The present technology relates to components and apparatuses for semiconductor manufacturing. More specifically, the present technology relates to substrate support assemblies and other semiconductor processing equipment.

### BACKGROUND

Integrated circuits are made possible by processes which produce intricately patterned material layers on substrate surfaces. Producing patterned material on a substrate requires controlled methods for forming and removing material. The temperature at which these processes occur may directly impact the final product. Substrate temperatures are often controlled and maintained with the assembly supporting the substrate during processing. Internally located heating devices may generate heat within the support, and the heat may be transferred conductively to the substrate. The substrate support may also be utilized in some technologies to develop a substrate-level plasma, as well as to chuck the substrate to the support electrostatically. Plasma generated near the substrate may cause bombardment of components, as well as parasitic plasma formation in unfavorable regions of the chamber. The conditions may also lead to discharge between substrate support electrodes. Additionally, utilizing the pedestal for both heat generation and plasma generation may cause interference effects.

As a variety of operational processes may utilize increased temperature as well as substrate-level plasma formation, constituent materials of the substrate support may be exposed to temperatures that affect the electrical operations of the assembly. Thus, there is a need for improved systems and methods that can be used to produce high quality devices and structures. These and other needs are addressed by the present technology.

### SUMMARY

Exemplary semiconductor processing chambers may include a chamber body. The chambers may include a bottom plate coupled with a bottom surface of the chamber body. The chambers may include a substrate support assembly disposed within the chamber body. The substrate support assembly may include a support plate and a support stem coupled with the support plate. The chambers may include a mounting bracket that couples the support stem with a lower surface of the bottom plate. The chambers may include a plurality of tilt actuators. Each of the plurality of tilt actuators may couple the mounting bracket with the lower surface of the bottom plate. Each of the plurality of tilt actuators may be operable to adjust a vertical distance between the lower surface of the bottom plate and the mounting bracket at a mounting site of the respective tilt actuator to adjust a planarity of the support plate relative to the bottom plate.

In some embodiments, the chambers may include a ball joint that vertically fixes a position of one point of the mounting bracket relative to the bottom plate. The plurality of tilt actuators may include two tilt actuators spaced apart from the ball joint. The chambers may include a faceplate seated atop the chamber body. Each of the plurality of tilt actuators may include a motor. Each of the plurality of tilt actuators may include a threaded member that is coupled with an output of the motor. Each of the plurality of tilt actuators may include a ramp actuator threadingly engaged with the threaded member. The ramp actuator may include an angled top surface. Each of the plurality of tilt actuators may include a mount support having an angled bottom surface. The angled bottom surface may be slidingly engaged with the angled top surface. Each of the plurality of tilt actuators may include an actuator mounting bracket. The ramp actuator may be slidable relative to the actuator mounting bracket. The actuator mounting bracket may be coupled with the mounting bracket. The mount support may be coupled with the lower surface of the bottom plate at a fixed location. The mount support may include a ball mount. The plurality of tilt actuators may be operable to adjust the planarity of the support plate to have a maximum tilt amplitude of at least 0.5 mm. The chambers may include a lift motor coupled with the support stem. The lift motor may be operable to translate the substrate support assembly vertically within the chamber body. The lift motor and the plurality of tilt actuators may be operable independently of one another.

Some embodiments of the present technology may encompass tilt actuators for a substrate support assembly. The actuators may include a motor. The actuators may include a threaded member that is coupled with an output of the motor. The actuators may include a ramp actuator threadingly engaged with the threaded member. The ramp actuator may include an angled top surface. The actuators may include a mount support comprising an angled bottom surface. The angled bottom surface may be slidingly engaged with the angled top surface. The actuators may include a mounting bracket. The ramp actuator may be slidable relative to the mounting bracket.

In some embodiments, the mount support may be configured to be secured to a bottom plate of a processing chamber. The mounting bracket may be configured to be coupled with a bracket that secures a substrate support assembly with a bottom plate of a processing chamber. The actuators may include a linear bearing disposed between the ramp actuator and the mounting bracket. The actuators may include a first hard stop that limits travel of the ramp actuator in a first direction relative to the mounting bracket. The actuators may include a second hard stop that limits travel of the ramp actuator in a second direction relative to the mounting bracket. The angled top surface and the angled bottom surface may be angled in opposite directions relative to horizontal.

Some embodiments of the present technology may encompass methods of processing a substrate. The methods may include positioning a substrate on a substrate support surface of a substrate support assembly. A mounting bracket may couple the substrate support assembly with a lower surface of a bottom plate of a processing chamber. The methods may include actuating at least one of a plurality of tilt actuators coupled with the mounting bracket to adjust a vertical distance between the lower surface of the bottom plate and the mounting bracket at a mounting site of the respective tilt actuator to adjust a planarity of a support plate of the substrate support assembly relative to the bottom plate. The methods may include flowing a precursor into a processing chamber. The methods may include generating a plasma of the precursor within a processing region of the processing chamber. The methods may include depositing a material on the substrate.

In some embodiments, the at least one of the plurality of tilt actuators may be actuated while the substrate support assembly is in a processing position. The at least one of the plurality of tilt actuators may be actuated while the substrate support assembly is in a transfer position. The at least one of the plurality of tilt actuators may be actuated while the precursor is flowing into the processing chamber.

Such technology may provide numerous benefits over conventional systems and techniques. For example, embodiments of the present technology may provide substrate support planarity actuators that take up less space than existing planarity actuators. Additionally, the designs described herein may enable smaller motors to be used to drive the planarity actuators. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic partial cross-sectional view of an exemplary processing chamber according to some embodiments of the present technology.

FIG. 4A shows a schematic partial isometric view of an exemplary processing chamber according to some embodiments of the present technology.

FIG. 4B shows a schematic partial isometric view of a substrate support assembly mounting bracket of the processing chamber of FIG. 4A.

FIG. 4C shows a schematic partial cross-sectional view of a substrate support assembly mounting bracket and bottom plate of the processing chamber of FIG. 4A.

FIG. 5A shows a schematic side elevation view of an exemplary tilt actuator in a neutral position according to some embodiments of the present technology.

FIG. 5B shows a schematic side elevation view of the tilt actuator of FIG. 5A in a lowered position according to some embodiments of the present technology.

FIG. 5C shows a schematic side elevation view of the tilt actuator of FIG. 5A in a raised position according to some embodiments of the present technology.

FIG. 5D shows a schematic cross-sectional view of the tilt actuator of FIG. 5A in a neutral position according to some embodiments of the present technology.

FIG. 6 shows exemplary operations in a processing method according to some embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

During semiconductor processing operations, such as deposition and etch operations, the substrates may experience various uniformity issues. In some processing chambers, the substrate support may be tilted to adjust the planarity of the substrate support surface to help combat planar uniformity issues. Some conventional chambers tilt the substrate support using manual adjustment mechanisms (e.g., screws, springs, wrenches, etc.) that are adjusted before every change in recipe or process. These adjustment mechanisms cannot be adjusted in situ and require human access and time. Other conventional chambers utilize three-axis planarity adjustment mechanisms that utilize three lift motors. Each lift motor may be independently controlled to adjust a tilt or planarity of the substrate support surface. However, these adjustment mechanisms take up significant space and may require complex motor controllers.

The present technology addresses these issues by incorporating a two-axis actuation mechanism, with a ball joint at a third position. Operation of the two-axis actuation mechanism may be used to control the planarity of the substrate support surface independent of the lift operation and may be performed in situ. Additionally, by using the two-axis actuation mechanism in place of three lift motors, significant space savings are possible.

Although the remaining disclosure will routinely identify specific deposition processes utilizing the disclosed technology, it will be readily understood that the systems and methods are equally applicable to other deposition, etching, and cleaning chambers, as well as processes as may occur in the described chambers. Accordingly, the technology should not be considered to be so limited as for use with these specific deposition processes or chambers alone. The disclosure will discuss one possible system and chamber that may include pedestals according to embodiments of the present technology before additional variations and adjustments to this system according to embodiments of the present technology are described.

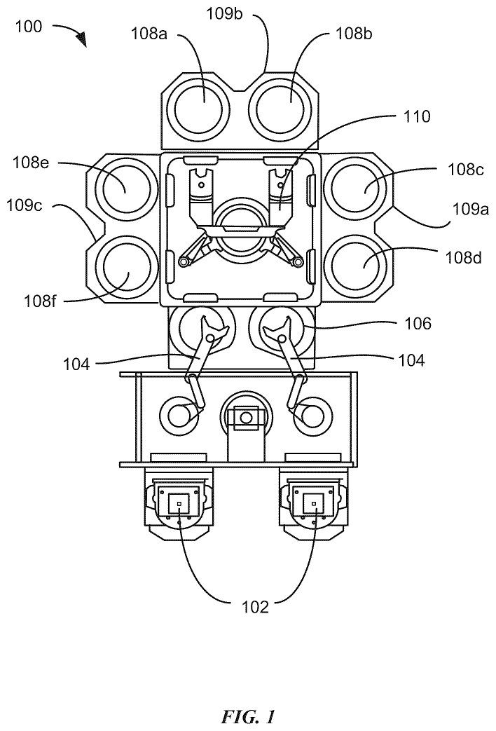

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

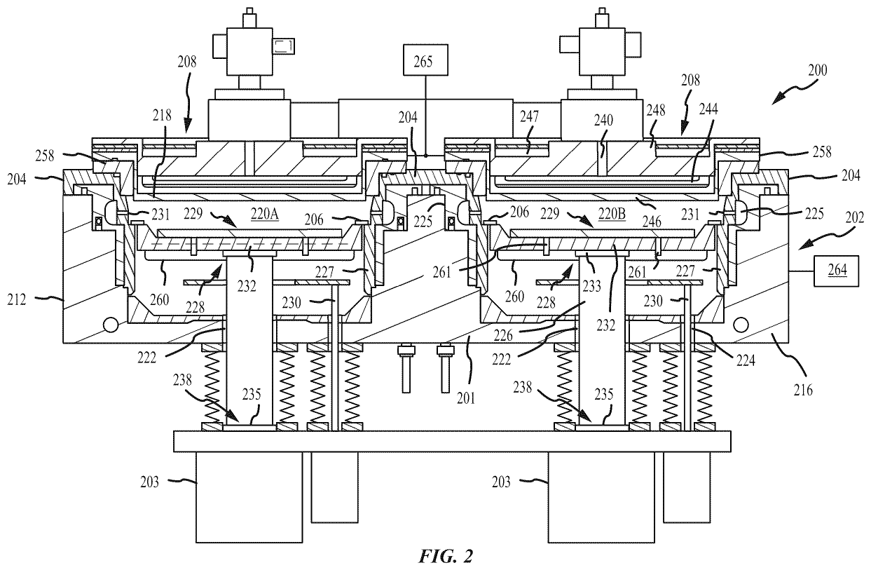

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include substrate support assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the gas distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

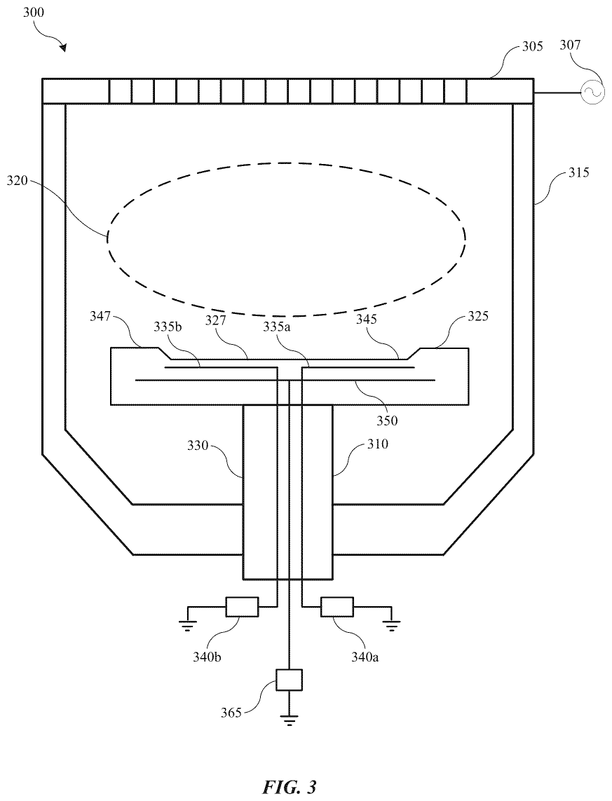

FIG. 3 shows a schematic partial cross-sectional view of an exemplary semiconductor processing chamber 300 according to some embodiments of the present technology. FIG. 3 may include one or more components discussed above with regard to FIG. 2 and may illustrate further details relating to that chamber. The chamber 300 may be used to perform semiconductor processing operations including deposition of stacks of dielectric materials as previously described. Chamber 300 may show a partial view of a processing region of a semiconductor processing system, and may not include all of the components, such as additional lid stack components previously described, which are understood to be incorporated in some embodiments of chamber 300.

As noted, FIG. 3 may illustrate a portion of a processing chamber 300. The chamber 300 may include a showerhead 305, as well as a substrate support assembly 310. Along with chamber sidewalls 315, the showerhead 305 and the substrate support 310 may define a substrate processing region 320 in which plasma may be generated. The substrate support assembly may include an electrostatic chuck body 325, which may include one or more components embedded or disposed within the body. The components incorporated within the top puck may not be exposed to processing materials in some embodiments and may be fully retained within the chuck body 325. Electrostatic chuck body 325 may define a substrate support surface 327 and may be characterized by a thickness and length or diameter depending on the specific geometry of the chuck body. In some embodiments the chuck body may be elliptical and may be characterized by one or more radial dimensions from a central axis through the chuck body. It is to be understood that the top puck may be any geometry, and when radial dimensions are discussed, they may define any length from a central position of the chuck body.

Electrostatic chuck body 325 may be coupled with a stem 330, which may support the chuck body and may include channels for delivering and receiving electrical and/or fluid lines that may couple with internal components of the chuck body 325. Chuck body 325 may include associated channels or components to operate as an electrostatic chuck, although in some embodiments the assembly may operate as or include components for a vacuum chuck, or any other type of chucking system. Stem 330 may be coupled with the chuck body on a second surface of the chuck body opposite the substrate support surface. In some embodiments, the electrostatic chuck body 325 may be formed from a conductive material (such as a metal like aluminum or any other material that may be thermally and or electrically conductive) and may be coupled with a source of electric power (such as DC power, pulsed DC power, RF bias power, a pulsed RF source or bias power, or a combination of these or other power sources) through a filter, which may be an impedance matching circuit to enable the electrostatic chuck body 325 to operate as an electrode. In other embodiments, a top portion of the electrostatic chuck body 325 may be formed from a dielectric material. In such embodiments, the electrostatic chuck body 325 may include separate electrodes. For example, the electrostatic chuck body 325 may include a first bipolar electrode 335a, which may be embedded within the chuck body proximate the substrate support surface. Electrode 335a may be electrically coupled with a DC power source 340a. Power source 340a may be configured to provide energy or voltage to the electrically conductive chuck electrode 335a. This may be operated to form a plasma of a precursor within the processing region 320 of the semiconductor processing chamber 300, although other plasma operations may similarly be sustained. For example, electrode 335a may also be a chucking mesh that operates as electrical ground for a capacitive plasma system including an RF source 307 electrically coupled with showerhead 305. For example, electrode 335a may operate as a ground path for RF power from the RF source 307, while also operating as an electric bias to the substrate to provide electrostatic clamping of the substrate to the substrate support surface. Power source 340a may include a filter, a power supply, and a number of other electrical components configured to provide a chucking voltage.

The electrostatic chuck body may also include a second bipolar electrode 335b, which may also be embedded within the chuck body proximate the substrate support surface. Electrode 335b may be electrically coupled with a DC power source 340b. Power source 340b may be configured to provide energy or voltage to the electrically conductive chuck electrode 335b. Additionally electrical components and details about bipolar chucks according to some embodiments will be described further below, and any of the designs may be implemented with processing chamber 300. For example, additional plasma related power supplies or components may be incorporated.

In operation, a substrate may be in at least partial contact with the substrate support surface of the electrostatic chuck body, which may produce a contact gap, and which may essentially produce a capacitive effect between a surface of the pedestal and the substrate. Voltage may be applied to the contact gap, which may generate an electrostatic force for chucking. The power supplies 340a and 340b may provide electric charge that migrates from the electrode to the substrate support surface where it may accumulate, and which may produce a charge layer having Coulomb attraction with opposite charges at the substrate, and which may electrostatically hold the substrate against the substrate support surface of the chuck body. This charge migration may occur by current flowing through a dielectric material of the chuck body based on a finite resistance within the dielectric for Johnsen-Rahbek type chucking, which may be used in some embodiments of the present technology.

Chuck body 325 may also define a recessed region 345 within the substrate support surface, which may provide a recessed pocket in which a substrate may be disposed. Recessed region 345 may be formed at an interior region of the top puck and may be configured to receive a substrate for processing. Recessed region 345 may encompass a central region of the electrostatic chuck body as illustrated, and may be sized to accommodate any variety of substrate sizes. A substrate may be seated within the recessed region, and contained by an exterior region 347, which may encompass the substrate. In some embodiments the height of exterior region 347 may be such that a substrate is level with or recessed below a surface height of the substrate support surface at exterior region 347. A recessed surface may control edge effects during processing, which may improve uniformity of deposition across the substrate in some embodiments. In some embodiments, an edge ring may be disposed about a periphery of the top puck, and may at least partially define the recess within which a substrate may be seated. In some embodiments, the surface of the chuck body may be substantially planar, and the edge ring may fully define the recess within which the substrate may be seated.

In some embodiments the electrostatic chuck body 325 and/or the stem 330 may be insulative or dielectric materials. For example, oxides, nitrides, carbides, and other materials may be used to form the components. Exemplary materials may include ceramics, including aluminum oxide, aluminum nitride, silicon carbide, tungsten carbide, and any other metal or transition metal oxide, nitride, carbide, boride, or titanate, as well as combinations of these materials and other insulative or dielectric materials. Different grades of ceramic materials may be used to provide composites configured to operate at particular temperature ranges, and thus different ceramic grades of similar materials may be used for the top puck and stem in some embodiments. Dopants may be incorporated in some embodiments to adjust electrical properties as well. Exemplary dopant materials may include yttrium, magnesium, silicon, iron, calcium, chromium, sodium, nickel, copper, zinc, or any number of other elements known to be incorporated within a ceramic or dielectric material.

Electrostatic chuck body 325 may also include an embedded heater 350 contained within the chuck body. Heater 350 may include a resistive heater or a fluid heater in embodiments. In some embodiments the electrode 335 may be operated as the heater, but by decoupling these operations, more individual control may be afforded, and extended heater coverage may be provided while limiting the region for plasma formation. Heater 350 may include a polymer heater bonded or coupled with the chuck body material, although a conductive element may be embedded within the electrostatic chuck body and configured to receive current, such as AC current, to heat the top puck. The current may be delivered through the stem 330 through a similar channel as the DC power discussed above. Heater 350 may be coupled with a power supply 365, which may provide current to a resistive heating element to facilitate heating of the associated chuck body and/or substrate. Heater 350 may include multiple heaters in embodiments, and each heater may be associated with a zone of the chuck body, and thus exemplary chuck bodies may include a similar number or greater number of zones than heaters. If present, the chucking mesh electrodes 335 may be positioned between the heater 350 and the substrate support surface 327 in some embodiments, and a distance may be maintained between the electrode within the chuck body and the substrate support surface in some embodiments as will be described further below.

The heater 350 may be capable of adjusting temperatures across the electrostatic chuck body 325, as well as a substrate residing on the substrate support surface 327. The heater may have a range of operating temperatures to heat the chuck body and/or a substrate above or about 100° C., and the heater may be configured to heat above or about 125° C., above or about 150° C., above or about 175° C., above or about 200° C., above or about 250° C., above or about 300° C., above or about 350° C., above or about 400° C., above or about 450° C., above or about 500° C., above or about 550° C., above or about 600° C., above or about 650° C., above or about 700° C., above or about 750° C., above or about 800° C., above or about 850° C., above or about 900° C., above or about 950° C., above or about 1000° C., or higher. The heater may also be configured to operate in any range encompassed between any two of these stated numbers, or smaller ranges encompassed within any of these ranges, as well as less than any of the stated temperatures. In some embodiments, the chamber 300 may include a purge gas source, such as a purge gas source fluidly coupled with a bottom of the chamber body. The purge gas source may supply a purge gas to the chamber 300 to remove any film that has been deposited on various components of the chamber 300, such as the support assembly 310.

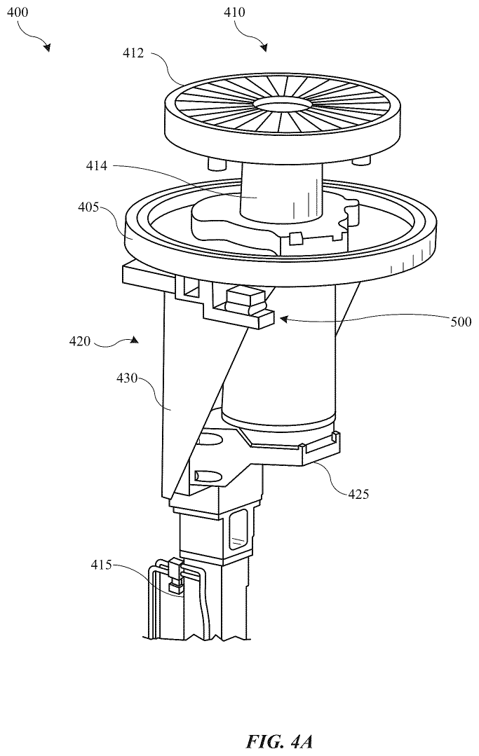

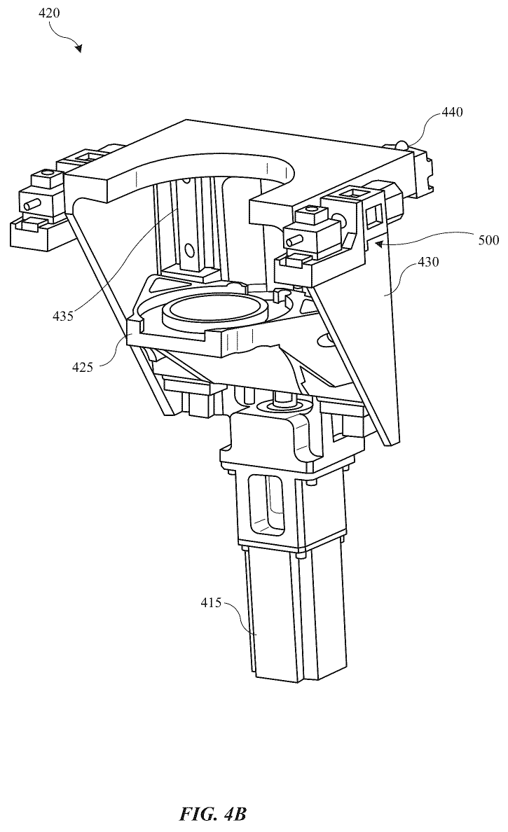

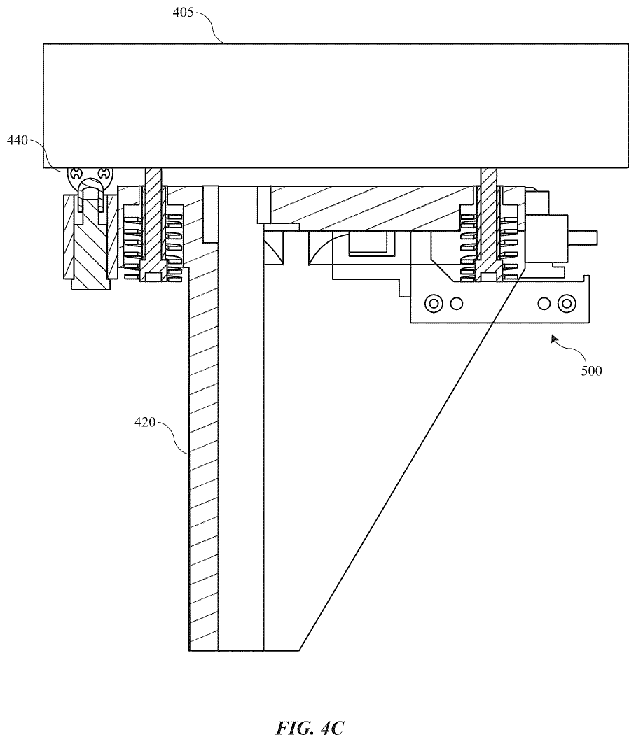

FIGS. 4A-4C show a schematic partial views of an exemplary semiconductor processing chamber 400 according to some embodiments of the present technology. FIGS. 4A-4C may include one or more components discussed above with regard to FIGS. 2 and 3 and may illustrate further details relating to that chamber. The chamber 400 may be used to perform semiconductor processing operations including deposition of stacks of dielectric materials as previously described. Chamber 400 may show a partial view of a semiconductor processing system, and may not include all of the components, such as additional lid stack components previously described, which are understood to be incorporated in some embodiments of chamber 400.

As noted, FIGS. 4A-4C may illustrate a portion of a processing chamber 400. The chamber 400 may include a bottom plate 405, which may be coupled with a bottom surface of a chamber body (such as sidewalls 212 of chamber body 202 and/or sidewalls 315 of chamber 300). Bottom plate 405 may define a bottom of an interior of processing chamber 400, such as defining a bottom boundary of a transfer region of processing chamber 400. Chamber 400 may include a substrate support assembly 410, which may be similar to substrate support assembly 310 or pedestal 228. Substrate support assembly 410 may include a support plate 412 and a support stem 414, which may be coupled with a lower surface of support plate 412. In some embodiments substrate support assembly 410 may be operated as a chuck, such as a vacuum chuck and/or an electrostatic chuck. Support plate 412 may be positioned above bottom plate 405, while support stem 414 may extend through an aperture formed through bottom plate 405. Substrate support assembly 410 may be vertically translatable within chamber 400, such as between a lower transfer position and a raised process position. Chamber 400 may include a lift motor 415 that may be coupled with support stem 414, such as at a bottom end of support stem 414. Lift motor 415 may be actuated to translate substrate support assembly 410 vertically within the chamber body (e.g., relative to bottom plate 405).

Chamber 400 may include a mounting bracket 420 that may couple support stem 414 with a lower surface of bottom plate 405. For example, as best illustrated in FIG. 4B, mounting bracket 420 may include a platform 425 that may receive and/or otherwise be secured with a bottom end of support stem 412. Platform 425 may be translatable relative to an outer bracket 430, such as by sliding along one or more tracks 435 that are disposed on an interior surface of outer bracket 430. Lift motor 415 may be coupled with a bottom end of platform 425 to raise and lower platform 425 (and substrate support assembly 410) relative to mounting bracket 420 and bottom plate 405. A top end of mounting bracket 420 may be coupled with bottom plate 405. For example, a number of tilt actuators 500 may be used to couple mounting bracket 420 with the lower surface of bottom plate 405. As illustrated, tilt actuators 500 are disposed on outer sides of mounting bracket 420, although other locations are possible. Any number of tilt actuators 500 may be included in various embodiments. For example, chamber 400 may include two or more tilt actuators, three or more tilt actuators, four or more tilt actuators, five or more tilt actuators, or more. In the illustrated embodiment, two tilt actuators 500 are coupled with mounting bracket 420 and bottom plate 405 at different mounting sites. At a third mounting site, a ball joint 440 may be provided to couple mounting bracket 420 and bottom plate 405. Ball joint 440 may vertically fix a position of one point of the mounting bracket 420 relative to bottom plate 405, while tilt actuators 500 may be actuated to adjust a vertical distance between the lower surface of bottom plate 405 and mounting bracket 420 at locations (e.g., mounting sites) of each tilt actuator 500 to adjust a planarity of support plate 412 relative to bottom plate 405 and/or a faceplate seated atop the chamber body. For example, one or more of the tilt actuators 500 may be adjusted to raise and/or lower mounting bracket 420 relative to bottom plate 405 at the respective mounting site. The raising or lowering of mounting bracket 420 at the mounting site of a tilt actuator 500 while ball joint 440 maintains a corresponding portion of mounting bracket 420 at a fixed vertical position relative to bottom plate 405 may result in mounting bracket 420 and support assembly 410 (including support plate 412) being tilted relative to bottom plate 405 and a faceplate seated atop the chamber body. The tilting of substrate support assembly 410 may be used to adjust the planarity of support plate 410 to combat planar non-uniformity deposition issues. In some embodiments, tilt actuators 500 may be maintained at a neutral position to maintain support plate 412 at a planar position (e.g., parallel to bottom plate 405 and the faceplate).

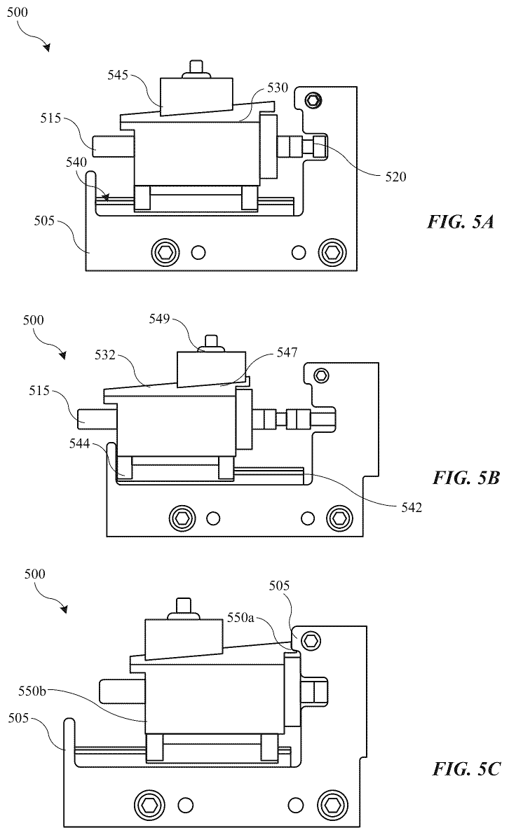

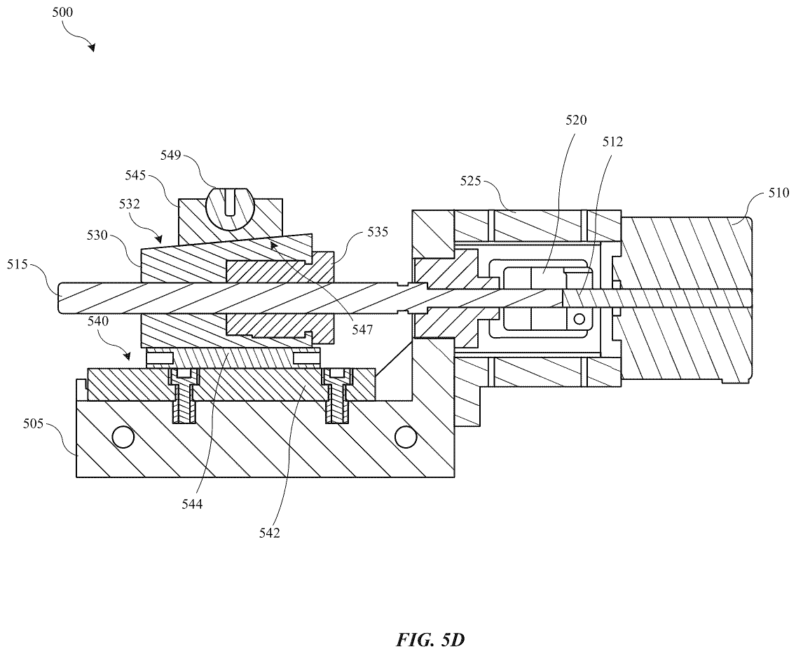

FIGS. 5A-5D illustrate different views of tilt actuator 500. As noted above, each tilt actuator 500 may be used to couple mounting bracket 420 with bottom plate 405. For example, tilt actuator 500 may include a mounting bracket 505 that may be coupled with mounting bracket 420, such as along a lateral surface of mounting bracket 420. Mounting bracket 505 may support other components of tilt actuator 500. For example, a motor 510, such as a servo motor, may be coupled with a portion of mounting bracket 505. In the illustrated embodiment, motor 510 may be directly or indirectly coupled with a lateral end of mounting bracket 505, although in some embodiments motor 510 may be supported atop a portion of mounting bracket 505. As best illustrated in the cross-section of FIG. 5D, tilt actuator 500 may include a threaded member 515 (such as a lead screw or ball screw assembly) that may be coupled with an output 512 (such as an output shaft) of motor 510. For example, a coupler 520 may be coupled between ends of threaded member 515 and output 512 of motor 510. Coupler 520 may be disposed within a housing 525 that extends between and couples a housing of motor 510 with mounting bracket 505.

Tilt actuator 500 may include a ramp actuator 530 that may be engaged with threaded member 515. For example, ramp actuator 530 may define a recess that receives an end support 535 that defines a threaded aperture. Threaded member 515 may be inserted within the threaded aperture to couple threaded member 515 with ramp actuator 530. Ramp actuator 530 may be slidable relative to mounting bracket 505 along a longitudinal axis of ramp actuator 530. In some embodiments, a linear bearing 540 may be disposed between ramp actuator 530 and mounting bracket 505 to facilitate smooth and/or relatively low friction sliding of ramp actuator 530 relative to mounting bracket 505. For example, linear bearing 540 may include a bearing rail 542 that may be coupled with ramp actuator 530 or mounting bracket 505 and a bearing car 544 that may be coupled with the other of ramp actuator 530 and mounting bracket 505. As illustrated, bearing rail 542 is coupled with mounting bracket 505 and bearing car 544 is coupled with ramp actuator 530. Bearing car 544 may be designed to slide along a length of bearing rail 542. For example, bearing car 544 may include a slot that receives and slides along a flange or other feature of bearing rail 542, with the flange preventing bearing car 544 from moving vertically relative to bearing rail 542.

Ramp actuator 530 may include an angled top surface 532, which may be sloped relative to horizontal. In some embodiments, an angle of the slope of top surface 532 may be between or about 5 degrees and 45 degrees relative to horizontal, between or about 5 degrees and 30 degrees relative to horizontal, or between or about 5 degrees and 15 degrees relative to horizontal, with smaller angles enabling smaller adjustments of a degree of tilt of mounting bracket 420 and substrate support assembly 410 while also requiring smaller motor torque to adjust the planarity of substrate support assembly 410. Tilt actuator 500 may include a mount support 545 that may be disposed above ramp actuator 530. For example, mount support 545 may include an angled bottom surface 547 that may be positioned against top surface 532 of ramp actuator 530. In some embodiments, an angle of the slope of bottom surface 547 may have a same magnitude and an opposite direction as the angle of top surface 532. For example, bottom surface 547 may have an angle of between or about −5 degrees and −45 degrees relative to horizontal, between or about −5 degrees and −30 degrees relative to horizontal, or between or about −5 degrees and −15 degrees relative to horizontal, with smaller angles enabling smaller adjustments of a degree of tilt of mounting bracket 420 and substrate support assembly 410 and requiring smaller motor torque to adjust the planarity of substrate support assembly 410.

Mount support 545 may be coupled with the bottom surface of bottom plate 405 to fix mount support 545 at a given position relative to bottom plate 405. For example, mount support 545 may include a ball mount 549 having a top end that is insertable within a receptacle formed within bottom plate 405 and a lower ball end that is rotatably received within a recess formed in mount support 545. Ball mount 549 may enable mount support 545 to be coupled with the lower surface of bottom plate 405 at a fixed location while helping to reduce the load and/or torque on motor 510. Bottom surface 547 may be slidable along a length of top surface 532, such as during movement of ramp actuator 530 relative to mounting bracket 505, to control a vertical distance between mounting bracket 505 (and mounting bracket 420) and bottom plate 405 to effectively control a planarity of substrate support assembly 410 relative to bottom plate 405 and a faceplate of the chamber 400.

For example, during operation, as motor 510 is operated, output 512 causes threaded member 515 to rotate. The engagement of threaded member 515 and the threads of end support 535 may push or pull ramp actuator 530 to different positions along a length of linear bearing 540 relative to a neutral position (e.g., shown in FIG. 5A). When ramp actuator 530 is moved in a first direction (as illustrated in FIG. 5B, pushed by motor 510, although the direction is dictated by the orientation of the slopes of top surface 532 and bottom surface 547), top surface 532 may slide relative to bottom surface 547 such that mount support 545 is positioned along a higher portion of ramp actuator 530, which may push ramp actuator 530 and mounting bracket 505 downward relative to the fixed position of mount support 545. This may increase the vertical distance between the mounting bracket 505 (and mounting bracket 420) and bottom plate 405 at the location of tilt actuator 500 (and in particular mount support 545). When ramp actuator 530 is moved in an opposite second direction (as illustrated in FIG. 5C, pulled by motor 510, although the direction is dictated by the orientation of the slopes of top surface 532 and bottom surface 547), top surface 532 may slide relative to bottom surface 547 such that mount support 545 is positioned along a lower portion of ramp actuator 530, which may pull ramp actuator 530 and mounting bracket 505 upward relative to the fixed position of mount support 545. This may decrease the vertical distance between the mounting bracket 505 (and mounting bracket 420) and bottom plate 405 at the location of tilt actuator 500 (and in particular mount support 545).

In some embodiments, tilt actuator 500 may include one or more hard stops 550 that limit travel of ramp actuator 530 relative to mounting bracket 505 in one or more directions. For example, hard stop 550a may be formed on a first end of ramp actuator 530 and may contact a portion of mounting bracket 505 or other static component to limit travel of ramp actuator 530 toward motor 510. Similarly, hard stop 550b may be formed on an opposite second end of ramp actuator 530 and may contact a portion of mounting bracket 505 or other static component to limit travel of ramp actuator 530 away from motor 510. It will be appreciated that other forms of hard stops may be utilized in various embodiments, including hard stops that are integrated into bearing rail 542 and/or bearing car 544. In some embodiments, one or more sliding interfaces (e.g., bearing rail 542 and bearing car 544, top surface 532 and bottom surface 547, etc.) may be lubricated to reduce abrasive wear between the components and/or to reduce the friction and subsequent load on motor 510.

By adjusting the position of ramp actuator 530 for one or more tilt actuators 500 (and keeping the vertical distance between mounting bracket 420 and bottom plate 405 fixed at the position of ball joint 440), a planarity of substrate support assembly 410 (and in particular support plate 414) may be adjusted. For example, operation of one or more tilt actuators 500 may be used to adjust the planarity of support plate 414 to have a maximum tilt amplitude (e.g., a vertical distance between a center of support plate 414 and a peripheral edge of support plate 414) of at least 0.5 mm, at least 0.75 mm, at least 1 mm, at least 1.25 mm, at least 1.5 mm, at least 1.75 mm, at least 2 mm, or more. In other words, support plate 414 may be tilted to any value within a range of between or about 0 mm and 2 mm, between or about 0 mm and 1.75 mm, between or about 0 mm and 1.5 mm, between or about 0 mm and 1.25 mm, between or about 0 mm and 1 mm, between or about 0 mm and 0.75 mm, or between or about 0 mm and 0.5 mm. Each tilt actuator 500 may be operated independently, and tilt actuators 500 may be operated independently of lift motor 415.

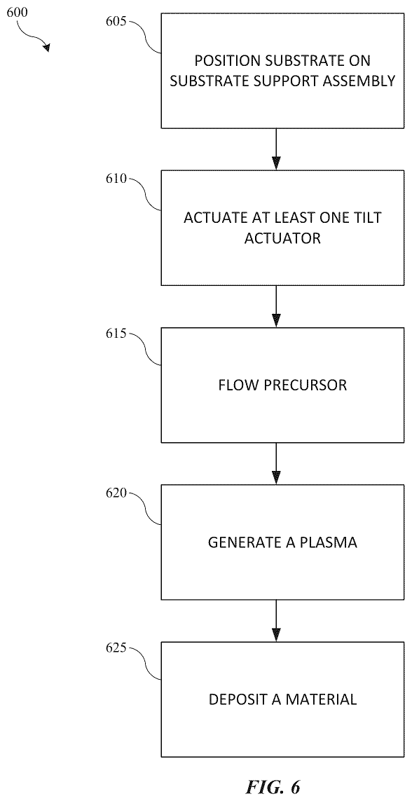

FIG. 6 shows operations of an exemplary method 600 of semiconductor processing according to some embodiments of the present technology. The method may be performed in a variety of processing chambers, including processing system 200, chamber 300, or chamber 400 described above, which may include substrate support assemblies and tilt actuators according to embodiments of the present technology, such as substrate support assembly 310 and 410 and tilt actuators 500 described herein. Method 600 may include a number of optional operations, which may or may not be specifically associated with some embodiments of methods according to the present technology.

Method 600 may include a processing method that may include operations for forming a hardmask film or other deposition operations. The method may include optional operations prior to initiation of method 600, or the method may include additional operations. For example, method 600 may include operations performed in different orders than illustrated. In some embodiments, method 600 may include positioning a substrate on a substrate support surface of a substrate support assembly at operation 605. A mounting bracket may couple the substrate support assembly with a lower surface of a bottom plate of a processing chamber, such as described in relation to FIGS. 4A-4C. At operation 610, at least one of a plurality of tilt actuators coupled with the mounting bracket may be actuated to adjust a vertical distance between the lower surface of the bottom plate and the mounting bracket at a mounting site of the respective tilt actuator to adjust a planarity of a support plate of the substrate support assembly relative to the bottom plate. For example, a motor of the tilt actuator may be operated to move a ramp actuator relative to a mount support that is fixedly coupled with the bottom plate of the chamber. Movement of the ramp actuator relative to the mount support may push the mounting bracket downward or pull the mounting bracket upward relative to the bottom plate of the chamber to adjust the vertical distance between the lower surface of the bottom plate and the mounting bracket at a mounting site of the respective tilt actuator. The vertical distance between the mounting bracket and the bottom plate of the chamber may be fixed at one location, such as at a ball joint, which may enable an adjustment of one or more of the tilt actuators to adjust the planarity of the substrate support assembly. The actuation of the one or more tilt actuators may occur at any time, such as while the substrate support assembly is in a transfer position, while the substrate support assembly is in a processing position, while the substrate support assembly is in transport between the transfer position and the processing position, and/or during processing operations (e.g., as a precursor and/or plasma is flowing into and/or otherwise present within the chamber).

One or more precursors may be flowed into a processing chamber at operation 615. For example, the precursor may be flowed into a chamber, such as chamber 300 or chamber 400. At operation 620, a plasma may be generated of the precursors within the processing region, such as by providing RF power to the faceplate and/or substrate support assembly to generate a plasma. Material formed in the plasma may be deposited on the substrate at operation 625. It will be appreciated that the operation of the tilt actuators may be used in other processing operations, such as etch operations in various embodiments.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing chamber, comprising:
a chamber body;
a bottom plate coupled with a bottom surface of the chamber body;
a substrate support assembly disposed within the chamber body, the substrate support assembly comprising a support plate and a support stem coupled with the support plate;
a mounting bracket that couples the support stem with a lower surface of the bottom plate; and
a plurality of tilt actuators, wherein:
each of the plurality of tilt actuators couples the mounting bracket with the lower surface of the bottom plate; and
each of the plurality of tilt actuators is operable to adjust a vertical distance between the lower surface of the bottom plate and the mounting bracket at a mounting site of the respective tilt actuator to adjust a planarity of the support plate relative to the bottom plate.

2. The semiconductor processing chamber of claim 1, further comprising:
a ball joint that vertically fixes a position of one point of the mounting bracket relative to the bottom plate, wherein the plurality of tilt actuators comprises two tilt actuators spaced apart from the ball joint.

3. The semiconductor processing chamber of claim 1, further comprising:
a faceplate seated atop the chamber body.

4. The semiconductor processing chamber of claim 1, wherein:
each of the plurality of tilt actuators comprises:
a motor;
a threaded member that is coupled with an output of the motor;
a ramp actuator threadingly engaged with the threaded member, wherein the ramp actuator comprises an angled top surface;
a mount support comprising an angled bottom surface, wherein the angled bottom surface is slidingly engaged with the angled top surface; and
an actuator mounting bracket, wherein the ramp actuator is slidable relative to the actuator mounting bracket.

5. The semiconductor processing chamber of claim 4, wherein:
the actuator mounting bracket is coupled with the mounting bracket.

6. The semiconductor processing chamber of claim 1, wherein:
the mount support is coupled with the lower surface of the bottom plate at a fixed location.

7. The semiconductor processing chamber of claim 6, wherein:
the mount support comprises a ball mount.

8. The semiconductor processing chamber of claim 1, wherein:
the plurality of tilt actuators are operable to adjust the planarity of the support plate to have a maximum tilt amplitude of at least 0.5 mm.

9. The semiconductor processing chamber of claim 1, wherein:
a lift motor coupled with the support stem, the lift motor being operable to translate the substrate support assembly vertically within the chamber body.

10. The semiconductor processing chamber of claim 9, wherein:
the lift motor and the plurality of tilt actuators are operable independently of one another.

11. A tilt actuator for a substrate support assembly, comprising:
a motor;
a threaded member that is coupled with an output of the motor;
a ramp actuator threadingly engaged with the threaded member, wherein the ramp actuator comprises an angled top surface;
a mount support comprising an angled bottom surface, wherein the angled bottom surface is slidingly engaged with the angled top surface; and
a mounting bracket, wherein the ramp actuator is slidable relative to the mounting bracket.

12. The tilt actuator for a substrate support assembly of claim 11, wherein:
the mount support is configured to be secured to a bottom plate of a processing chamber.

13. The tilt actuator for a substrate support assembly of claim 11, wherein:
the mounting bracket is configured to be coupled with a bracket that secures a substrate support assembly with a bottom plate of a processing chamber.

14. The tilt actuator for a substrate support assembly of claim 3, further comprising:
a linear bearing disposed between the ramp actuator and the mounting bracket.

15. The tilt actuator for a substrate support assembly of claim 11, further comprising:
a first hard stop that limits travel of the ramp actuator in a first direction relative to the mounting bracket; and
a second hard stop that limits travel of the ramp actuator in a second direction relative to the mounting bracket.

16. The tilt actuator for a substrate support assembly of claim 11, wherein:
the angled top surface and the angled bottom surface are angled in opposite 2 directions relative to horizontal.

17. A method of processing a substrate, comprising:
positioning a substrate on a substrate support surface of a substrate support assembly, wherein a mounting bracket couples the substrate support assembly with a lower surface of a bottom plate of a processing chamber;
actuating at least one of a plurality of tilt actuators coupled with the mounting bracket to adjust a vertical distance between the lower surface of the bottom plate and the mounting bracket at a mounting site of the respective tilt actuator to adjust a planarity of a support plate of the substrate support assembly relative to the bottom plate;
flowing a precursor into a processing chamber;
generating a plasma of the precursor within a processing region of the processing chamber; and
depositing a material on the substrate.

18. The method of processing a substrate of claim 17, wherein:
the at least one of the plurality of tilt actuators is actuated while the substrate support assembly is in a processing position.

19. The method of processing a substrate of claim 17, wherein:
the at least one of the plurality of tilt actuators is actuated while the substrate support assembly is in a transfer position.

20. The method of processing a substrate of claim 17, wherein:
the at least one of the plurality of tilt actuators is actuated while the precursor is flowing into the processing chamber.
